(19) United States
(12) Patent Application Publication
(10) Pub. No.: US 2025/0254836 A1
(43) Pub. Date: Aug. 7, 2025

(54) RADIATIVE HEAT DISSIPATION CASING

(71) Applicant: Taiwan Ruomei Technology Corp., Taipei City (TW)

(72) Inventors: Hou-Yu Lee, Taipei City (TW); Si-Han Lin, Taipei City (TW)

(73) Assignee: Taiwan Ruomei Technology Corp., Taipei City (TW)

(21) Appl. No.: 19/031,957

(22) Filed: Jan. 18, 2025

(30) Foreign Application Priority Data
Feb. 7, 2024 (TW) 113105148

(51) Int. Cl. H05K 7/20

(52) U.S. Cl. CPC H05K 7/20409; H05K 7/20445

(57) ABSTRACT

A radiative heat dissipation casing, including: an enclosure, which including a radiative heat dissipation unit whose material composition includes an aluminum oxide-boron nitride-fullerene composite material, for an enhanced thermal radiation dissipation; a heat generation element, disposed inside the enclosure; and an internal heat transfer bridge, disposed between the heat generation element and the enclosure, wherein the waste heat from the heat generation element is transferred via the internal heat transfer bridge to the radiative heat dissipation unit and then radiated to the outside of the enclosure.

### CROSS REFERENCE

The present invention claims priority to TW113105148 filed on Feb. 7, 2024.

### BACKGROUND OF THE INVENTION

### Field of Invention

The present invention relates radiative heat dissipation casing that transfers waste heat from the inside of the enclosure to the outside of an electrical device.

### Description of Related Art

Usually, the cooling technology for the electrical device employs thermal conduction or convection, to transfer the waste heat inside the enclosure to the outside thereof. For example, the waste heat inside the enclosure can be transferred to the outside through force convection, with facilities including cooling fins and a fan. In this way, the cooling fins and the fans can occupy a significant portion of internal space within the enclosure. Further, the heat exchange process can generate noise and consume considerable power. When the heat dissipation demand becomes higher, the number of cooling fins can be correspondingly more, to occupy more space for setting up these cooling fins and fans. Thus, this cooling design is both space-intensive and power-hungry.

### SUMMARY OF THE INVENTION

Regarding the aforementioned technical requirements, the present invention provides a radiative heat dissipation casing, including: an enclosure, including a radiative heat dissipation unit whose material composition includes an aluminum oxide-boron nitride-fullerene composite material, for an enhanced thermal radiation dissipation; a heat generation element, disposed inside the enclosure; and an internal heat transfer bridge, disposed between the heat generation element and the radiative heat dissipation unit, wherein the waste heat from the heat generation element can be transferred via the internal heat transfer bridge to the radiative heat dissipation unit, and then radiated to the outside of the enclosure through the radiative heat dissipation unit.

In one embodiment, a molding material of the enclosure includes the aluminum oxide-boron nitride-fullerene composite material, to form the radiative heat dissipation unit on a surface of the molding material; or, a blending material includes the aluminum oxide-boron nitride-fullerene composite material, covering an outer surface of the enclosure to form the radiative heat dissipation unit; or, the radiative heat dissipation casing includes an insert part (embedded within the enclosure) to constitute the radiative heat dissipation unit, and a material composition of the insert part includes the aluminum oxide-boron nitride-fullerene composite material,

In one embodiment, the insert part is disposed on the enclosure at a position corresponding to the heat generation element.

In one embodiment, the internal heat transfer bridge includes a solid thermal conduction portion, a thermal convection liquid, or a gas, to convey the waste heat from the heat generation element to the radiative heat dissipation unit.

In one embodiment, a solid thermal conduction portion is connected between the heat generation element and the radiative heat dissipation unit. The solid thermal conduction portion is substantially made of a high thermal conductivity material.

In one embodiment, the gas within the enclosure conveys the waste heat from the heat generation element to the radiative heat dissipation unit, by natural or forced convection.

In one embodiment, the radiative heat dissipation casing further includes a thermal convection circulation unit, which employs a working fluid in a chamber of the thermal convection circulation unit, to convey the waste heat from the heat generation element by convective circulation, to the radiative heat dissipation unit.

In one embodiment, the aluminum oxide-boron nitride-fullerene composite material includes plural micro-composite particles. In each of the micro-composite particles, the aluminum oxide is disposed at the center of the micro-composite particle, and encircled by plural sandwich structures. Each of the sandwich structures can be formed with a disposition sequence of boron nitride, fullerene, and boron nitride. In one embodiment, the preferable particle size range for the micro-composite particles can be from 0.01 μm to 60 μm. The fullerene has a C60 molecular structure in a long capsule-like shape.

In one embodiment, the radiative heat dissipation casing further includes a venting hole, disposed on a portion of the enclosure within the radiative heat dissipation unit, or disposed on a portion of the enclosure outside the radiative heat dissipation unit.

The objectives, technical details, features, and effects of the present invention can be better understood with regard to the detailed description of the embodiments below, with reference to the associated drawings.

### BRIEF DESCRIPTION OF THE DRAWINGS

FIGS. 1, 2, 3, and 4 respectively illustrate cross-sectional schematic diagrams of several radiative heat dissipation casings according to multiple embodiments of the present invention.

FIG. 5 illustrates a schematic diagram of a micro-composite particle of the aluminum oxide-boron nitride-fullerene composite material according to one embodiment of the present invention.

FIG. 6 illustrates a schematic diagram of a sandwich structure within the aluminum oxide-boron nitride-fullerene composite material according to one embodiment of the present invention.

FIG. 7 illustrates a schematic diagram of a molecular structure of the fullerene in a long capsule-like shape according to one embodiment of the present invention.

FIGS. 8 and 9 illustrate cross-sectional schematic diagrams of the radiative heat dissipation casing according to two embodiments of the present invention.

### DESCRIPTION OF THE PREFERRED EMBODIMENTS

The technical wordings/terms in this specification are based on customary understanding in the art. When any wording/term is described or defined in this specification, the interpretation of the term/wording is primarily based on the description or the definition set forth in this specification. Each embodiment of the present invention includes one or more technical features. To the extent possible, a person having ordinary knowledge in the art may combine or modify these features, whether in whole or in part, within the scope and spirit of this invention.

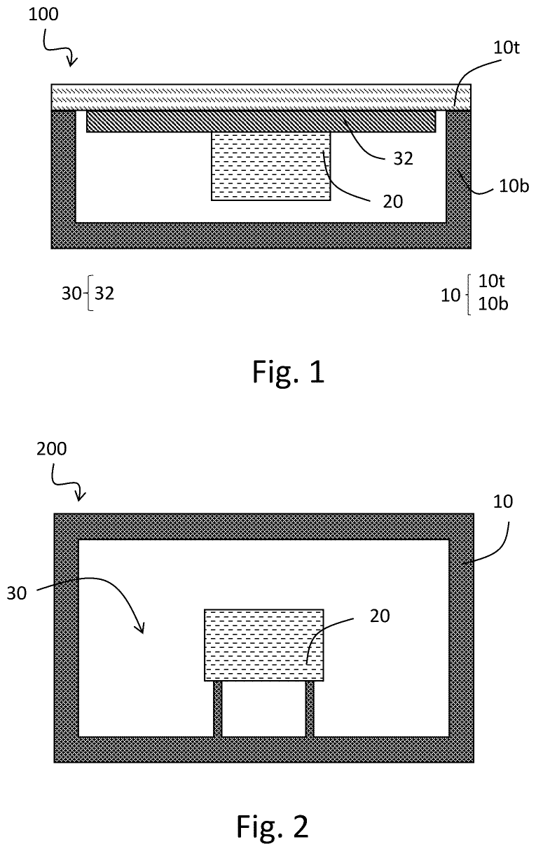

Referring to FIGS. 1 and 2, with respect to the aforementioned technical needs, the present invention provides a radiative heat dissipation casing 100 (or 200), including: an enclosure 10 (In FIG. 1, the enclosure 10 includes a top cover 10t and a bottom cover 10b. In FIG. 2, the enclosure 10 can be formed as a single component, or manufactured as a single-piece structure), the enclosure 10 including a radiative heat dissipation unit (In FIG. 1, the top cover 10t serves the radiative heat dissipation unit. In FIG. 2, the enclosure 10 serves the radiative heat dissipation unit), the material of the radiative heat dissipation unit including an aluminum oxide-boron nitride-fullerene composite material, for an enhanced thermal radiation dissipation; a heat generation element 20, disposed inside the enclosure 10; and an internal heat transfer bridge 30, disposed between the heat generation element 20 and the enclosure 10. The waste heat of the heat generation element 20 is transferred via the internal heat transfer bridge 30 to the radiative heat dissipation unit, which transfers/radiates the waste heat to the outside of the enclosure 10 by thermal radiation.

Importantly, the absolute temperature T in the thermal radiation formula P=εσAT⁴ exhibits a quadratic form equation, so that the formula value change of the thermal radiation corresponds to a quadratic temperature dependence (temperature high order term), which can, in certain scenarios, be significantly more effective at cooling than the linear temperature dependence of thermal conduction. In the formula, ε denotes the surface emissivity of the object, σ denotes the Stefan-Boltzmann constant, and A denotes the surface area of the object. When the emissivity of the surface of the object is high, the effect of thermal radiation for cooling can be very considerable. Moreover, the convection cooling in a high-temperature working environment poses a challenge, especially when relying on convection with a limited temperature difference due to the high-temperature working environment. Under such conditions, the thermal radiation cooling can remain highly effective, even at elevated temperatures.

In one embodiment, a molding material of the enclosure 10 includes an aluminum oxide-boron nitride-fullerene composite material (e.g., the aluminum oxide-boron nitride-fullerene composite material mixed in the molding material of the enclosure 10), and the radiative heat dissipation unit can be formed on the surface of the molding material. For example, the molding materials of the top cover 10t of FIG. 1, and the enclosure 10 of FIG. 2, can have mixed material with the aluminum oxide-boron nitride-fullerene composite material, and the radiative heat dissipation unit can be formed on the surface of the molding material. Or, a blending material (e.g., a covering material) includes the aluminum oxide-boron nitride-fullerene composite material, to cover the outer surface 12 of the enclosure 10 to form the radiative heat dissipation unit (e.g., in the radiative heat dissipation casing in FIG. 3, a covering layer PA of the blending material is deposited and covered on the outer surface 12 of the enclosure 10 as the radiative heat dissipation unit). Or, referring to FIG. 4, the radiative heat dissipation casing 400 includes an insert part 40, which is embedded within the enclosure 10. The material composition of the insert part 40 includes the aluminum oxide-boron nitride-fullerene composite material. An outer side of the insert part 40 can constitute the radiative heat dissipation unit on the enclosure 10, to be a key portion for performing thermal radiation dissipation on the enclosure 10. Importantly, the radiative heat dissipation unit of the aforementioned embodiment can dissipate the waste heat efficiently without the fan.

In one embodiment, the weight ratio of aluminum oxide-boron nitride-fullerene composite material in the composition of the molding material, preferably ranges from 1% to 5%, with an optimal weight ratio of 2%.

In one embodiment, the internal heat transfer bridge 30 can also have a surface-to-surface contact design, such as the surface-to-surface thermal contact for heat transfer between the insert part 40 and the heat generation element 20 in FIG. 4, which can transfer the waste heat from the heat generation element 20 through the internal heat transfer bridge 30, to the radiative heat dissipation unit (the outer side of the insert part 40), and then radiate the waste heat to the outside of the enclosure 10.

In one embodiment, the insert part 40 can be disposed within the enclosure 10 at a position corresponding to the heat generation element 20. In this way, the internal heat transfer bridge 30 can transfer waste heat from the heat generation element 20 to the radiative heat dissipation unit (or the outer side of the insert part 40) in a short distance.

In one embodiment, the internal heat transfer bridge 30 includes a solid thermal conduction portion, a thermal convection liquid, or a gas, to convey the waste heat from the heat generation element 20 to the radiative heat dissipation unit.

In the foregoing embodiments, the internal heat transfer bridge 30 may have different design options. In one embodiment, a solid thermal conduction portion 32 (FIG. 1) is connected between the heat generation element 20 and the radiative heat dissipation unit, wherein the solid thermal conduction portion 32 is made of a high thermal conductivity material, such as graphene, diamond, silver, copper, gold, aluminum, or the aluminum oxide-boron nitride-fullerene composite material.

In one embodiment shown in FIG. 2, by filling the gas between the enclosure 10 and the heat generation element 20 corresponding to the internal heat transfer bridge 30, the gas inside the enclosure 10 can convey the waste heat of the heat generation element 20 into the internal heat transfer bridge 30 (the space accommodating the gas), by natural convection or forced convection.

In one embodiment, the radiative heat dissipation casing further includes a thermal convection circulation unit, conveying (or transferring) the waste heat from the heat generation element to the radiative heat dissipation unit, by circulating a working fluid in a chamber of the thermal convection circulation unit. For example, the thermal convection circulation unit includes a heat sink. The working fluid within the thermal convection circulation unit, can carry out the thermal energy exchange between the heat generation element and the radiative heat dissipation unit by thermal energy exchanges by the working fluid in the same phase (or with phase changes) between the heat generation element and the radiative heat dissipation unit. Therein, the thermal convection circulation unit can be combined with other thermal radiation technologies of the present invention, to greatly improve the heat dissipation capability.

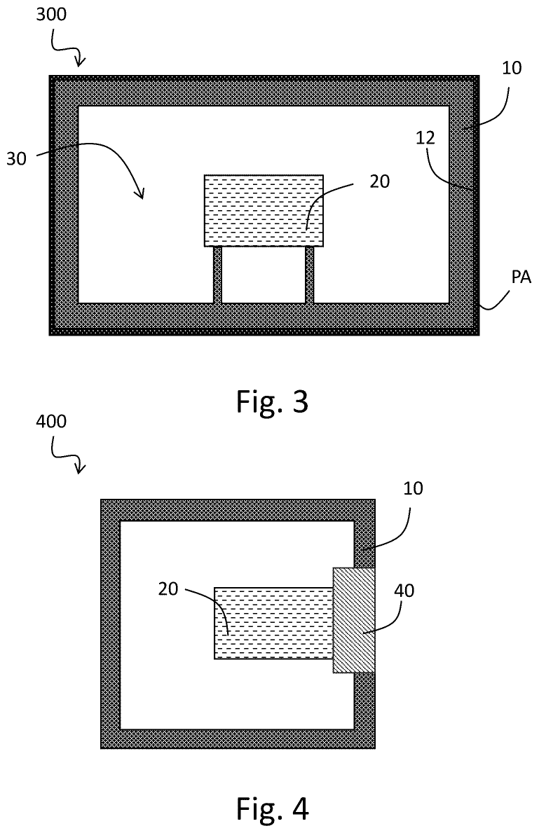

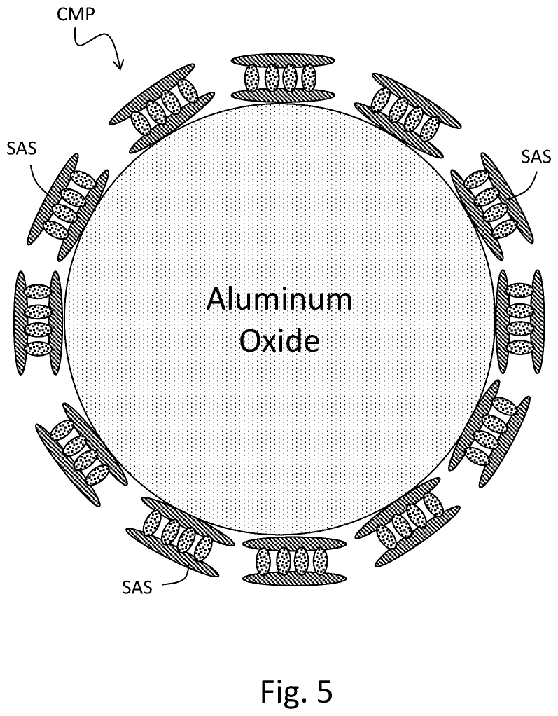

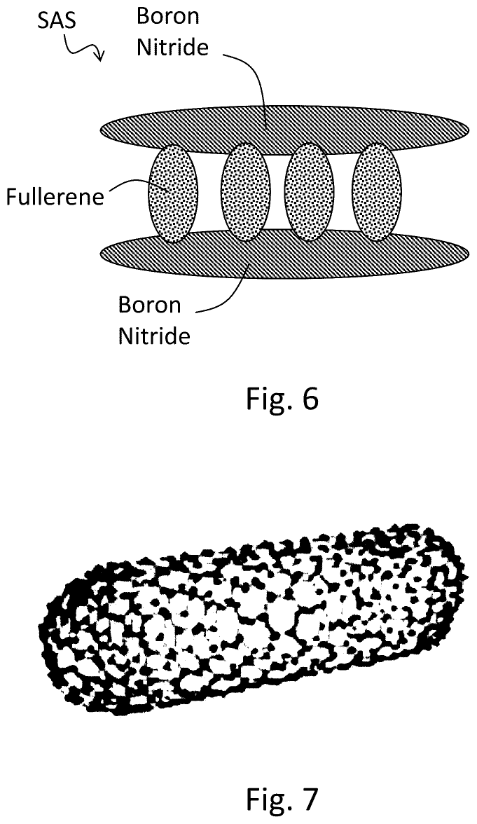

In one embodiment, the aluminum oxide-boron nitride-fullerene composite material includes plural micro-composite particles CMP (FIG. 5 showing schematic cross-section view of the micro-composite particle CMP). In each of the micro-composite particles CMP, the aluminum oxide is disposed at the center of the micro-composite particle CMP, and encircled by a number of the sandwich structures SAS (the number of the sandwich structures SAS in the drawing is only illustrative). Each of the sandwich structures SAS can be formed with a disposition sequence of boron nitride, fullerene, and boron nitride. The sides of the sandwich structures SAS facing the aluminum oxide dispose the boron nitrides (referring to FIGS. 5 and 6). The fullerene may have different disposition directions: a longitude direction, defining the longest scale of a long capsule-like shape of the fullerene, is different from a latitude direction, which defines the shortest scale of the long capsule-like shape of the fullerene. In the sandwich structures SAS, the fullerenes are disposed between the two boron nitrides, and the number of fullerenes shown in the drawings is only illustrative. The aforementioned composite material can be made by combining various materials in a physical or chemical way. The fullerene of the present invention has a C60 molecular formula (a molecular structure composed of sixty carbon atoms). The fullerenes applied in the present invention have a long capsule-like molecular structure. In FIG. 7, the bold black dots denote the carbon atoms, which are different from the traditional spherical molecular structure of the fullerene, wherein the carbon atoms are distributed on the surface of the spherical shape. The fullerene in the long capsule-like shape has an excellent performance of thermal radiation and electrical conductivity. In the sandwich structures SAS, the two boron nitrides surround the fullerenes, to isolate the conductivity between the fullerenes of the same sandwich structure SAS, and between the fullerenes of the different sandwich structures SAS. Therefore, the sandwich structures SAS have excellent thermal radiation capability and electrical isolation property. Therein, the capsule-shaped fullerene applied in the current invention has a high surface emissivity of 0.98 (ε denotes the surface emissivity in the aforementioned thermal radiation formula).

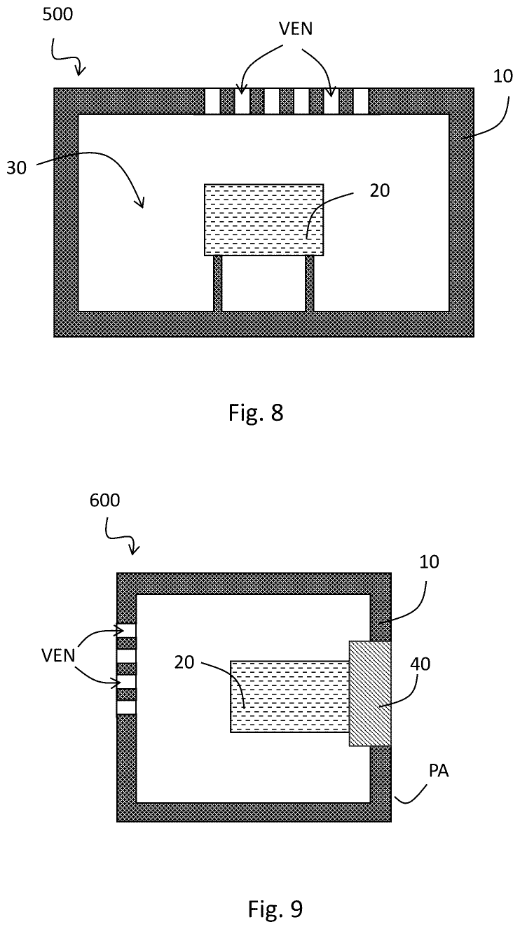

The heat radiation technology of the present invention can also be combined with conventional cooling technologies. In one embodiment, the radiative heat dissipation casing further includes venting holes VEN, which can be disposed on a portion of the enclosure 10 within the radiative heat dissipation unit (e.g., the radiative heat dissipation casing 500 shown in FIG. 8, the venting hole VEN is disposed on a portion of the enclosure 10, within the radiative dissipation unit of the aforementioned molding material). Or, the venting holes VEN can be disposed on a portion of the enclosure 10 outside the radiative heat dissipation unit (e.g., the radiative heat dissipation casing 600 shown in FIG. 9, wherein the venting holes VEN are disposed outside the radiative heat dissipation unit which disposes the insert part 40). Further, the enclosure 10 can dispose a venting hole matrix on the enclosure 10, within or outside the radiative heat dissipation unit, and it is known technology and not elaborated herein.

The above disclosure provides different features in embodiments or examples for implementing the present invention. The examples of components and configurations are described above by illustrating the implementations of the present invention. Of course, these components and configurations are for illustrative purposes only and not intended to limit the scope of the present invention. In addition, some embodiments of the present invention may include repeated reference symbols and/or marks of the elements between different drawings. This repetition is for simplicity and clarity purposes, and does not confine any implementation between the various embodiments and/or configurations.

Further, those who have common knowledge in the art to which the present invention belongs, may make modifications and embellishments without departing from the scope of the present invention, which can be defined according to the claims of the present invention.

What is claimed is:

1. A radiative heat dissipation casing, including:
an enclosure, including a radiative heat dissipation unit whose material composition includes an aluminum oxide-boron nitride-fullerene composite material for an enhanced thermal radiation dissipation;
a heat generation element, disposed inside the enclosure; and
an internal heat transfer bridge, disposed between the heat generation element and the enclosure, wherein waste heat generated from the heat generation element is transferred via the internal heat transfer bridge to the radiative heat dissipation unit and then radiated to the outside of the enclosure.

2. The radiative heat dissipation casing according to claim 1, wherein a molding material of the enclosure includes the aluminum oxide-boron nitride-fullerene composite material to form the radiative heat dissipation unit on a surface of the molding material; or, a blending material includes the aluminum oxide-boron nitride-fullerene composite material, to cover an outer surface of the enclosure to form the radiative heat dissipation unit; or, the radiative heat dissipation casing further includes an insert part embedded within the enclosure, to constitute the radiative heat dissipation unit on the enclosure, wherein the material composition of the insert part includes the aluminum oxide-boron nitride-fullerene composite material.

3. The radiative heat dissipation casing according to claim 2, wherein the insert part, is disposed on the enclosure at a position corresponding to the heat generation element.

4. The radiative heat dissipation casing according to claim 1, wherein the internal heat transfer bridge conveys the waste heat from the heat generation element to the radiative heat dissipation unit, through a solid thermal conduction portion, a thermal convection liquid, or a gas.

5. The radiative heat dissipation casing according to claim 4, wherein the solid thermal conduction portion is connected between the heat generation element and the radiative heat dissipation unit, wherein the solid thermal conduction portion is substantially made of high thermal conductivity material.

6. The radiative heat dissipation casing according to claim 4, wherein the gas within the enclosure conveys the waste heat from the heat generation element to the radiative heat dissipation unit by natural convection or forced convection.

7. The radiative heat dissipation casing, according to claim 4, further including a thermal convection circulation unit which conveys the waste heat from the heat generation element by circulating a working fluid in a chamber of the thermal convection circulation unit, to the radiative heat dissipation unit.

8. The radiative heat dissipation casing according to claim 1, wherein the aluminum oxide-boron nitride-fullerene composite material includes plural micro-composite particles, wherein in each of the micro-composite particles, the aluminum oxide is disposed at the center and encircled by plural sandwich structures, and each of the sandwich structures is formed with a disposition sequence of boron nitride, fullerene, and boron nitride.

9. The radiative heat dissipation casing according to claim 1, wherein of the micro-composite particles have a preferable particle size ranging from 0.01 μm to 60 μm.

10. The radiative heat dissipation casing according to claim 1, wherein the fullerene has a C60 molecular structure in a long capsule-like shape.

11. The radiative heat dissipation casing according to claim 1, wherein the enclosure includes a venting hole, disposed on a portion of the enclosure within the radiative heat dissipation unit, or disposed on a portion of the enclosure outside the radiative heat dissipation unit.
